(19) United States
(12) Patent Application Publication
(10) Pub. No.: US 2026/0305152 A1
(43) Pub. Date: Oct. 1, 2026

(54) APPARATUS AND METHOD FOR MANUFACTURING DISPLAY DEVICE, AND ELECTRONIC DEVICE INCLUDING THE DISPLAY DEVICE

(71) Applicant: Samsung Display Co., Ltd., Yongin-si (KR)

(72) Inventors: Suhwan Lee, Yongin-si (KR); Minwoo Kim, Yongin-si (KR); Chunyoung Park, Yongin-si (KR); Jungho Lee, Yongin-si (KR); Chanyang Lim, Yongin-si (KR); Seonmean Jeong, Yongin-si (KR); Yeontaek Jung, Yongin-si (KR); Seungin Choi, Yongin-si (KR); Jungwoo Hwang, Yongin-si (KR); Seungjoo Baek, Yongin-si (KR)

(21) Appl. No.: 19/568,270

(22) Filed: Mar. 16, 2026

(30) Foreign Application Priority Data
Mar. 28, 2025 (KR) 10-2025-0040481
Jul. 4, 2025 (KR) 10-2025-0090313

(51) Int. Cl. H10K 71/16; H10K 59/12

(52) U.S. Cl. CPC H10K 71/166; H10K 59/1201

(57) ABSTRACT

An apparatus includes a chamber where a substrate is disposed, and a deposition source disposed inside the chamber and supplying a deposition material onto the substrate, where the deposition source includes a housing including therein a passage through which a refrigerant circulates, a deposition material supply unit disposed inside the housing, storing the deposition material, and including a nozzle guiding the deposition material to the outside, a heater unit disposed outside the deposition material supply unit and heating the deposition material supply unit, a reflector disposed above the housing and shielding an internal space of the housing, and an insulator disposed between the reflector and the housing to block movement of heat.

This application claims priority to Korean Patent Application No. 10-2025-0040481, filed on Mar. 28, 2025, and Korean Patent Application No. 10-2025-0090313, filed on Jul. 4, 2025, and all the benefits accruing therefrom under 35 U.S.C. § 119, the contents of which in their entirety are herein incorporated by reference.

### BACKGROUND

### 1. Field

One or more embodiments relate to an apparatus and method, and more particularly, to an apparatus and method for manufacturing a display device, and an electronic device.

### 2. Description of the Related Art

Electronic devices based on mobility are widely used. Recently, tablet personal computers, in addition to small-sized electronic devices such as mobile phones, continue to be widely used as mobile electronic devices.

To support various functions, such mobile electronic devices include display devices to provide visual information, such as an image or a video, to a user. Recently, with the miniaturization of components for driving the display devices, the proportions of the display devices occupying the electronic devices continue to gradually increase, and the display devices having structures that are bendable from flat states to have predetermined angles continue to be developed.

### SUMMARY

An intermediate layer may be arranged between a pixel electrode and an opposite electrode to manufacture a display device. Here, a deposition material may be deposited on a substrate to form at least one layer of the intermediate layer. The deposition material may be heated, and the heated deposition material may be supplied from a deposition source to the substrate. In this case, the deposition material may be adhered not only to the substrate, but also to at least a portion of the deposition source, and thus, the deposition source may malfunction or the lifespan of the deposition source may be reduced. One or more embodiments include an apparatus and method for manufacturing a display device, in which the amount of a deposition material adhered to a deposition source is reduced, and an electronic device manufactured via the method.

Additional features will be set forth in part in the description which follows and, in part, will be apparent from the description, or may be learned by practice of the presented embodiments.

In an embodiment of the disclosure, an apparatus for manufacturing a display device, includes a chamber where a substrate is disposed, and a deposition source disposed inside the chamber and supplying a deposition material onto the substrate, where the deposition source includes a housing including therein a passage through which a refrigerant circulates, a deposition material supply unit disposed inside the housing, storing the deposition material, and including a nozzle guiding the deposition material to the outside, a heater unit disposed outside the deposition material supply unit and heating the deposition material supply unit, a reflector disposed above the housing and shielding an internal space of the housing, and an insulator disposed between the reflector and the housing to block movement of heat.

In an embodiment, the deposition source may further include a heat sink disposed between the reflector and the deposition material supply unit.

In an embodiment, the insulator may include at least one of polyetheretherketone, wholly aromatic polyimide, carbon composite, and ceramic.

In an embodiment, the deposition source may further include an angle restricting plate disposed on the reflector and restricting a path of the deposition material ejected from the nozzle.

In an embodiment, the reflector may include a shielding protrusion shielding a space between one surface of the reflector, where the angle restricting plate is disposed (e.g., mounted), and the angle restricting plate.

In an embodiment, a side surface of the shielding protrusion may face the end of the angle restricting plate, disposed (e.g., mounted) on the reflector.

In an embodiment, the shielding protrusion may be separated from the angle restricting plate.

In an embodiment, at least a portion of the reflector may be bent.

In an embodiment of the disclosure, an apparatus for manufacturing a display device, includes a chamber where a substrate is disposed, and a deposition source disposed inside the chamber and supplying a deposition material onto the substrate, where the deposition source includes a housing including therein a passage through which a refrigerant circulates, a deposition material supply unit disposed inside the housing, storing the deposition material, and including a nozzle guiding the deposition material to the outside, a heater unit disposed outside the deposition material supply unit and heating the deposition material supply unit, a reflector disposed above the housing and shielding an internal space of the housing, and an angle restricting plate disposed on the reflector and restricting a path of the deposition material ejected from the nozzle, where an end of the angle restricting plate disposed on the reflector is disposed to correspond to a point of the reflector at which the reflector starts to bend.

In an embodiment, the apparatus may further include a shielding protrusion shielding a space between the angle restricting plate and one surface of the reflector.

In an embodiment, a side surface of the shielding protrusion may face an end of a portion of an angle restricting plate support unit.

In the illustrated embodiment, the shielding protrusion may be separated from the angle restricting plate support unit.

In an embodiment of the disclosure, a method of manufacturing a display device, includes arranging a substrate and a mask assembly inside a chamber, supplying a deposition material by a deposition source including a deposition material supply unit storing the deposition material, when the deposition material is supplied, matching an end of a portion of an angle restricting plate support unit, where an angle restricting plate is disposed, to a bending point of a reflector disposed around the deposition material supply unit and including at least a portion that is bent, blocking a space between the angle restricting plate support unit and the reflector disposed on a top surface of the deposition material supply unit, or blocking a heat exchange between the reflector and a housing in which the deposition material supply unit is accommodated, that includes a top surface where the reflector is disposed, and through which a refrigerant circulates, and depositing the deposition material on the substrate through the mask assembly.

In an embodiment, the method may further include arranging an insulator between the reflector and the housing.

In an embodiment, the insulator may include at least one of polyetheretherketone, wholly aromatic polyimide, carbon composite, and ceramic.

In an embodiment, the space between the angle restricting plate support unit and the reflector may be shielded by a shielding protrusion protruding from the reflector.

In an embodiment, a side surface of the shielding protrusion may face the end of the portion of the angle restricting plate support unit.

In an embodiment, the shielding protrusion may be separated from the angle restricting plate support unit.

In an embodiment of the disclosure, an electronic device includes the display device manufactured by the apparatus above, and a memory connected to the display device.

In an embodiment, the electronic device may include a smartphone, a tablet computer, a laptop personal computer, a desk monitor, smart glasses, a head-mounted display, a smart watch, a vehicle, a billboard, an electronic board, a game console, a refrigerator, a washing machine, a dryer, an air conditioner, or a robot vacuum cleaner.

Aspects, features, and advantages other than those described above may become clear from the following drawings, the claims, and the detailed description of the disclosure.

These general and predetermined features may be practiced using a system, method, computer program, or any combination of systems, methods, and computer programs.

### BRIEF DESCRIPTION OF THE DRAWINGS

The above and other aspects, features, and advantages of illustrative embodiments will be more apparent from the following description taken in conjunction with the accompanying drawings, in which:

FIG. 1 is a cross-sectional view schematically showing an apparatus for manufacturing a display device, according to an embodiment;

FIG. 2A is a cross-sectional view schematically showing a deposition source of FIG. 1, according to an embodiment;

FIG. 2B is a plan view schematically showing an arrangement of a reflector and a nozzle of FIG. 2A;

FIG. 3A is a cross-sectional view schematically showing another embodiment of a deposition source of FIG. 1;

FIG. 3B is an enlarged cross-sectional view of a region A of FIG. 3A;

FIG. 4A is a cross-sectional view schematically showing another embodiment of a deposition source of FIG. 1;

FIG. 4B is an enlarged cross-sectional view of a region B of FIG. 4A;

FIG. 5A is a cross-sectional view schematically showing an embodiment of a deposition source of FIG. 1;

FIG. 5B is an enlarged cross-sectional view of a region C of FIG. 5A;

FIG. 6 is a plan view schematically showing a display device according to an embodiment;

FIG. 7 is a circuit diagram schematically showing a circuit of the display device of FIG. 6;

FIG. 8 is a cross-sectional view showing a portion of the display device of FIG. 6;

FIG. 9 is a block diagram of an electronic device according to an embodiment; and

FIGS. 10 to 12 are schematic diagrams of embodiments of an electronic device.

### DETAILED DESCRIPTION

The disclosure may have various modifications and various embodiments, and illustrative embodiments are illustrated in the drawings and are described in detail in the detailed description. Effects and features of the disclosure and methods of achieving the same will become apparent with reference to embodiments described in detail below with reference to the drawings. However, the disclosure is not limited to the embodiments described below, and may be implemented in various forms.

Hereinafter, embodiments will be described in detail with reference to the accompanying drawings, and in the following description with reference to the drawings, like reference numerals refer to like components and redundant descriptions thereof will be omitted.

As used herein, the term “and/or” includes any and all combinations of one or more of the associated listed items. Throughout the disclosure, the expression “at least one of a, b, and c” indicates only a, only b, only c, both a and b, both a and c, both b and c, all of a, b, and c, or variations thereof.

In the following embodiments, the terms “first” and “second” are not used in a limited sense and are used to distinguish one component from another component.

In the following embodiments, an expression used in the singular encompasses the expression of the plural, unless it has a clearly different meaning in the context.

It will be further understood that the terms “include” and/or “comprise” used herein specify the presence of stated features or components, but do not preclude the presence or addition of one or more other features or components.

In the following embodiments, when a part such as a layer, a region, or a component is referred to as being “on” or “above” another part, the part may be directly on the other part or another layer, region, or component may be present therebetween.

In the drawings, for convenience of description, sizes of components may be exaggerated or reduced. For example, because sizes and thicknesses of components in the drawings are arbitrarily illustrated for convenience of explanation, the disclosure is not necessarily limited thereto.

In the following embodiments, an u-axis, a v-axis, and a w-axis are not limited to three axes on an orthogonal coordinate system, but may be interpreted in a broad sense including the three axes. For example, the u-axis, the v-axis, and the w-axis may be perpendicular to one another, or may represent different directions that are not perpendicular to one another.

When an illustrative embodiment may be implemented differently, a predetermined process order may be performed differently from the described order. For example, two consecutively described processes may be performed substantially at the same time or performed in an order opposite to the described order.

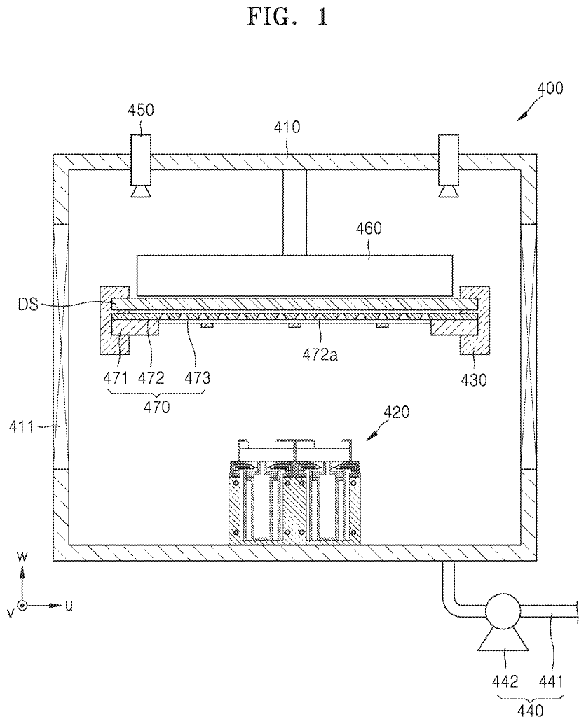

FIG. 1 is a cross-sectional view schematically showing an apparatus 400 for manufacturing a display device, according to an embodiment.

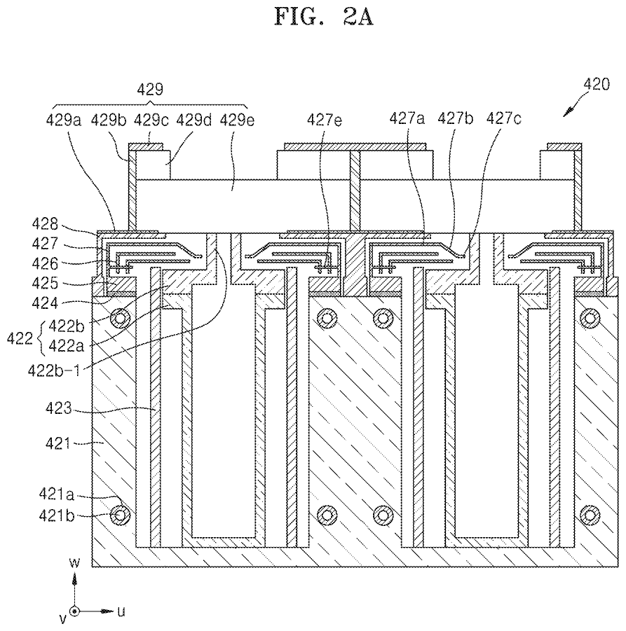

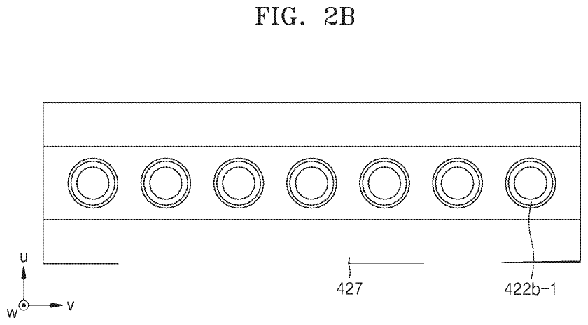

FIG. 2A is a cross-sectional view schematically showing a deposition source 420 of FIG. 1, according to an embodiment. FIG. 2B is a plan view schematically showing an arrangement of a reflector 427 and a nozzle 422b-1 of FIG. 2A.

Referring to FIGS. 1 to 2B, the apparatus 400 for manufacturing a display device may include a chamber 410, the deposition source 420, a support unit 430, a pressure adjusting unit 440, a vision unit 450, a distance adjusting unit 460, and a mask assembly 470.

A space is provided inside the chamber 410, and the chamber 410 may include a gate valve 411 that may be opened or closed. When the gate valve 411 is opened, the chamber 410 may communicate with the outside, and when the gate valve 411 is closed, the chamber 410 may be disconnected from the outside.

The deposition source 420 may store a deposition material and supply the deposition material by heating the deposition material. The deposition source 420 may be fixed to the chamber 410. The deposition source 420 may be in any one of various forms. In an embodiment, the deposition source 420 may be disposed at the center of the chamber 410 to supply the deposition material in the form of a dot, for example. In another embodiment, the deposition source 420 may be linear and disposed at the center of the chamber 410. Here, the length direction of the deposition source 420 may be the same as or perpendicular to the movement direction (e.g., a u direction or a v direction of FIG. 1) of a display substrate DS. Hereinafter, for convenience of description, an embodiment in which the deposition source 420 is in the form of a line and the length direction of the deposition source 420 is the same as the movement direction of the display substrate DS will be mainly described in detail.

The deposition source 420 may include a housing 421, a deposition material supply unit 422, a heater unit 423, an insulator 424, a support connecting unit 425, a heat sink 426, the reflector 427, an angle restricting plate support unit 428, and an angle restricting plate 429.

The housing 421 may form the exterior of the deposition source 420 and provide a space therein. Here, the housing 421 may include a refrigerant pipe 421a inserted into the housing 421 such that a refrigerant circulates, and the refrigerant pipe 421a may form a refrigerant passage (also being referred to as a passage) 421b. In another embodiment, the refrigerant passage 421b may be disposed inside the housing 421 and may be a space in which the refrigerant moves while a portion of the housing 421 is removed. Hereinafter, for convenience of description, an embodiment in which the housing 421 includes the refrigerant pipe 421a will be mainly described in detail. The refrigerant pipe 421a may be disposed along an edge of the housing 421. Here, the refrigerant pipe 421a may be disposed in the form of zigzags or in the form of a serpentine, in a direction (e.g., the v direction or the u direction of FIG. 1) parallel to a bottom surface of the housing 421 or in the height direction (e.g., a w direction of FIG. 1) of the housing 421.

A form of the housing 421 may correspond to a form of the deposition source 420. In an embodiment, when the deposition source 420 supplies the deposition material in the form of a dot, the housing 421 may have a polygonal column shape or a cylindrical shape, for example. In another embodiment, when the deposition source 420 is linear, the housing 421 may extend lengthwise in one direction (e.g., the u direction or the v direction of FIG. 1).

The deposition material supply unit 422 may be disposed inside the housing 421 and store the deposition material. Here, the deposition material inside the deposition material supply unit 422 may be vaporized by heat applied from the heater unit 423. There may be at least one deposition material supply unit 422. When the deposition material supply unit 422 is provided in plural, the plurality of deposition material supply units 422 may be arranged next (adjacent) to each other in the width direction (e.g., one of the v direction and the u direction of FIG. 1) of each deposition material supply unit 422. The width direction of each deposition material supply unit 422 may be perpendicular to the length direction (e.g., a remaining (the other) one of the v direction and the u direction of FIG. 1) of each deposition material supply unit 422.

The deposition material supply unit 422 may include a crucible 422a and a nozzle unit 422b, which are coupled to each other. The crucible 422a may store the deposition material therein and vaporize or sublimate the deposition material by heat applied from the outside. The nozzle unit 422b may open or close an open portion of the crucible 422a and include at least one nozzle 422b-1 to guide the deposition material to an outside of the deposition material supply unit 422. A cross-section of the nozzle 422b-1 perpendicular to the length direction (e.g., the w direction of FIG. 1) of the nozzle 422b-1 may be circular, elliptical, or polygonal. Hereinafter, for convenience of description, an embodiment in which the cross-section of the nozzle 422b-1 perpendicular to the length direction of the nozzle 422b-1 is circular will be mainly described in detail. When the nozzle 422b-1 is provided in plural, the plurality of nozzles 422b-1 may be spaced apart from each other in a line along the length direction of the deposition source 420.

The heater unit 423 may be disposed between the housing 421 and the deposition material supply unit 422 and be configured to generate heat. The heater unit 423 is illustrated as being disposed on a side surface of the deposition material supply unit 422. However, an embodiment is not limited thereto, and the heater unit 423 may be disposed on a top surface, a side surface, and/or a bottom surface of the deposition material supply unit 422. The heater unit 423 may include at least one heater. When the heater unit 423 includes a plurality of heaters, the plurality of heaters may be spaced apart from each other on a side surface of the crucible 422a. In another embodiment, some of the plurality of heaters may be arranged on the side surface of the crucible 422a, some other heaters may be arranged on a top surface of the crucible 422a, and some other heaters may be arranged on a bottom surface of the crucible 422a. The heater may include a sheathe heater.

The insulator 424 disposed on a top surface of the housing 421 may include a material having relatively low thermal conductivity and may be disposed between the support connecting unit 425 and the housing 421 to block heat exchange between the housing 421 and the support connecting unit 425. In an embodiment, the insulator 424 may include a material having thermal conductivity that is lower than thermal conductivity of the housing 421, for example. In detail, the insulator 424 may include an insulating material, e.g., a plastic-based material such as wholly aromatic polyimide or polyetheretherketone (“PEEK”), a carbon composite, and/or a ceramic-based material including ceramic (e.g., alumina, silicon nitride, boron nitride, zirconia, and/or magnesia). In an embodiment, the insulator 424 may include a material excluding a metal, depending on a material evaporating from the crucible 422a, for example.

The support connecting unit 425 may be disposed on the insulator 424. The support connecting unit 425 may be integrated with or separated from the reflector 427 to fix the reflector 427. The support connecting unit 425 may be in the form of a block and support the reflector 427. Hereinafter, for convenience of description, an embodiment in which the support connecting unit 425 is integrated with the reflector 427 will be mainly described in detail.

The heat sink 426 may be disposed above the support connecting unit 425 while spaced apart therefrom, and protrude from the support connecting unit 425 towards the nozzle 422b-1. At t his time, a portion of the heat sink 426 may be bent. The heat sink 426 may be connected to the reflector 427. In an embodiment, the heat sink 426 may be disposed between the reflector 427 and the deposition material supply unit 422. The heat sink 426 may be provided in plural, and the plurality of heat sinks 426 may be spaced apart from each other. The heat sink 426 may prevent a temperature of the nozzle 422b-1 and an ambient temperature of the nozzle 422b-1 from rapidly changing by not only allowing heat generated in the heater unit 423 to remain around the nozzle 422b-1 but also collecting some of the heat of the heater unit 423 and transferring radiant heat or convection heat towards the nozzle 422b-1.

The reflector 427 may be connected to the support connecting unit 425 and disposed above the nozzle unit 422b to prevent impurities (e.g., the deposition material) from entering into a space formed by the nozzle unit 422b, the housing 421, and the support connecting unit 425. Also, the reflector 427 may surround external surfaces of the deposition material supply unit 422 (e.g., the nozzle 422b-1) to prevent a material inside the chamber 410 from entering between the deposition material supply unit 422 and the housing 421. The reflector 427 may not only prevent heat inside the deposition material supply unit 422 from escaping to the outside, but also prevent a temperature inside the deposition material supply unit 422 from changing due to an external environment of the deposition material supply unit 422. In particular, the reflector 427 may surround the nozzle 422b-1 to prevent a sudden temperature change of the nozzle 422b-1 in the length direction of the nozzle 422b-1. At least a portion of the reflector 427 may be bent. In an embodiment, the reflector 427 may include a first portion 427a that is disposed (e.g., mounted) on the support connecting unit 425 and flat, a second portion 427b that is bent from the first portion 427a and inclined, and a third portion 427c that is bent from the second portion 427b and extends flat from the second portion 427b to the periphery of the nozzle 422b-1, for example. The first portion 427a may be in the form of a flat plate and coupled to the support connecting unit 425. Here, the first portion 427a may not be provided separately from the support connecting unit 425 but may be integrated with the support connecting unit 425. The second portion 427b may be disposed next (adjacent) to an end of the heat sink 426. Here, the second portion 427b may partially shield a space between the heat sinks 426 by inclining in a direction lowering from the first portion 427a. The reflector 427 may include a protruding portion 427e protruding from the first portion 427a. The protruding portion 427e may be protrude towards the nozzle 422b-1 and coupled to the heat sink 426 to support the heat sink 426.

Such a reflector 427 may define an opening area corresponding to the nozzle 422b-1. A planar shape of the opening area may correspond to a cross-sectional shape of the nozzle 422b-1. Also, the planar shape of each opening area may be greater than the cross-sectional shape of the nozzle 422b-1. Accordingly, an inner surface of each opening area may be spaced apart from an outer surface of the nozzle 422b-1.

The angle restricting plate support unit 428 may be connected to the housing 421. The angle restricting plate support unit 428 may be integrated with the housing 421 or may be separately formed and coupled to the housing 421. The insulator 424 may not be disposed between the angle restricting plate support unit 428 and the housing 421 to prevent a temperature of the angle restricting plate 429 from increasing. Hereinafter, for convenience of description, an embodiment in which the angle restricting plate support unit 428 is provided separately from the housing 421 and is coupled and fixed to the housing 421 will be mainly described in detail.

In an embodiment, the angle restricting plate 429 may be disposed above the reflector 427 and restricts a path of the deposition material ejected from the nozzle 422b-1. The angle restricting plate 429 may be coupled or connected to the angle restricting plate support unit 428, and may be supported by the angle restricting plate support unit 428. The angle restricting plate 429 may include a base 429a, a first restricting plate 429b, a second restricting plate 429c, a third restricting plate 429d, and a fourth restricting plate 429e. The base 429a may be in the form of a plate, disposed on one surface of the angle restricting plate support unit 428, and coupled to the angle restricting plate support unit 428. The first restricting plate 429b may be connected to the base 429a by being disposed perpendicular to one surface of the base 429a. The first restricting plate 429b may be in the form of a plate disposed between next (adjacent) deposition material supply units 422 or on a side surface of the deposition material supply unit 422. In an embodiment, the first restricting plate 429b may be disposed parallel to a first plane (e.g., a vw plane of FIG. 2A), for example. The second restricting plate 429c may be in the form of a plate, disposed perpendicular to the first restricting plate 429b, and connected to the first restricting plate 429b. The second restricting plate 429c may extend in parallel to a second plane (e.g., a vu plane of FIG. 2A). The third restricting plate 429d may be connected perpendicularly to the first restricting plate 429b in a direction different from a second direction (e.g., a u direction of FIG. 2A). The third restricting plate 429d may be disposed parallel to a third plane (e.g., a wu plane of FIG. 2A). The fourth restricting plate 429e may be in the form of a plate and disposed parallel to the third plane as the third restricting plate 429d. The fourth restricting plate 429e may connect the first restricting plates 429b that are next (adjacent) to each other. Such an angle restricting plate 429 may be disposed at the top of the deposition source 420 to determine an ejecting angle of the deposition material supplied from the deposition material supply unit 422.

The support unit 430 may support the display substrate DS and the mask assembly 470. The support unit 430 may simultaneously support the display substrate DS and the mask assembly 470 or may separately support the display substrate DS and the mask assembly 470. Such a support unit 430 may be provided in one piece or in a plurality of pieces to be separable from each other. The support unit 430 may be in any one of various forms. In an embodiment, the support unit 430 may be in the form of a shuttle that may linearly move inside the chamber 410 and move outside the chamber 410, for example. In another embodiment, the support unit 430 may be in the form of a member capable of moving linearly inside the chamber 410. Hereinafter, for convenience of description, an embodiment in which the support unit 430 simultaneously supports the display substrate DS and the mask assembly 470 and is in the form of a shuttle that may linearly move inside and outside the chamber 410 will be mainly described in detail.

The pressure adjusting unit 440 may be connected to the chamber 410 and adjust pressure inside the chamber 410. The pressure adjusting unit 440 may include a connection pipe 441 connected to the chamber 410 and a pump 442 provided at the connection pipe 441.

The vision unit 450 is disposed in the chamber 410 and may photograph locations of the display substrate DS and the mask assembly 470.

The distance adjusting unit 460 is disposed in the chamber 410 to not only adjust a distance between the display substrate DS and a mask sheet 472, but also prevent the mask sheet 472 from sagging due to a weight. The distance adjusting unit 460 may provide a magnetic force or an electromagnetic force to the mask sheet 472.

The mask assembly 470 may include a mask frame 471 and the mask sheet 472. The mask frame 471 may define an opening at a center portion thereof. In an embodiment, the mask frame 471 may be in the form of a picture frame or a window frame, for example. The mask sheet 472 may be disposed on the mask frame 471 and define a plurality of opening areas 472a therein. The plurality of opening areas 472a may be spaced apart from each other and may be arranged inside the opening of the mask frame 471. There may be at least one mask sheet 472. When there is one mask sheet 472, the mask sheet 472 may be disposed on the mask frame 471 to shield the entirety of the opening region of the mask frame 471. When there are a plurality of mask sheets 472, the plurality of mask sheets 472 may be arranged next (adjacent) to each other in one direction. In an embodiment, when the length direction of each mask sheet 472 is a first direction (e.g., the u direction of FIG. 1), the plurality of mask sheets 472 may be arranged next (adjacent) to each other in the second direction (e.g., the v direction of FIG. 1), for example.

As such, when the plurality of mask sheets 472 are provided, the mask assembly 470 may include at least one support frame 473 disposed in the opening region of the mask frame 471. The at least one support frame 473 may support the mask sheet 472. In this case, the at least one support frame 473 may be disposed below a portion between the mask sheets 472 next (adjacent) to each other and in parallel to the length direction of the mask sheet 472. In another embodiment, the at least one support frame 473 may not only support the mask sheet 472, but also divide the opening region of the mask frame 471 into a plurality of opening regions to distinguish a plurality of deposition regions. At least one of a plurality of support frames 473 may be disposed below a portion between the mask sheets 472 that are next (adjacent) to each other and parallel to the length direction of the mask sheet 472, and another one of the plurality of support frames 473 may be disposed to have a predetermined angle with the length direction of the mask sheet 472.

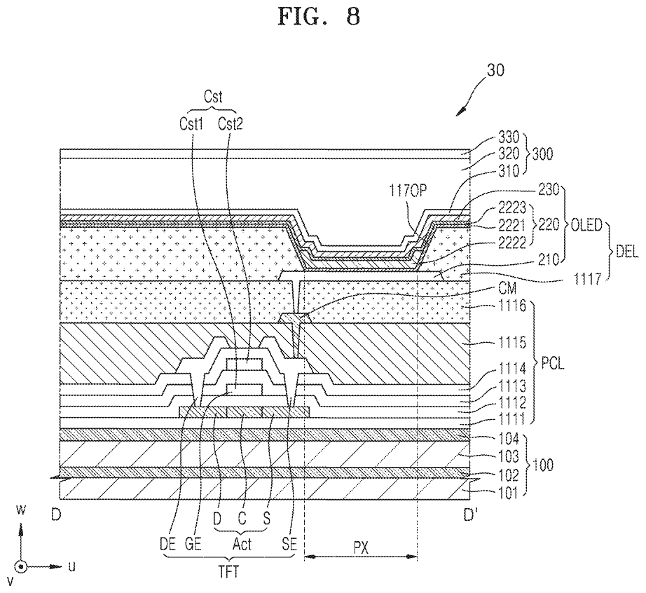

When a display device is manufactured, the display substrate DS may be inserted into the chamber 410 from the outside of the chamber 410. The display substrate DS may refer to layers from a substrate 100 (refer to FIG. 8) described below to a layer disposed below a layer that is formed via deposition using the apparatus 400. In an embodiment, when the apparatus 400 forms an emission layer 2222 among an intermediate layer 220 of FIG. 8, the display substrate DS may refer to layers from the substrate 100 of FIG. 8 to a first functional layer 2221 among the intermediate layer 220, for example.

The mask assembly 470 may be disposed to face the display substrate DS. Here, the display substrate DS and the mask assembly 470 may simultaneously enter the chamber 410 through the support unit 430 while being arranged in the support unit 430. In another embodiment, the display substrate DS and the mask assembly 470 may be arranged in the support unit 430 by separately entering into the chamber 410 from the outside of the chamber 410.

When the display substrate DS and the mask assembly 470 are arranged inside the chamber 410 as described above, the deposition source 420 may supply the deposition material. In detail, to supply the deposition material, the heater unit 423 may heat not only the crucible 422a, but also at least a portion of the nozzle unit 422b. At this time, the heat sink 426 may prevent a temperature from rapidly changing at each portion of the nozzle unit 422b. In an embodiment, the reflector 427 may shield an internal space of the housing 421. Also, the reflector 427 may shield the deposition material supply unit 422 at the end of the nozzle 422b-1 to prevent impurities from entering a space formed by the deposition material supply unit 422, the reflector 427, and the housing 421. In addition, the reflector 427 may block heat of the deposition material supply unit 422, thereby preventing a temperature of one surface of the display substrate DS, on which the deposition material is deposited, from increasing due to the deposition material supply unit 422. The deposition material may be adhered on a top surface of the reflector 427. At this time, when a temperature of the reflector 427 is too low, the deposition material may be adhered on the top surface of the reflector 427 and harden before reaching the display substrate DS. In particular, when supplying the deposition material from the deposition material supply unit 422, the refrigerant may circulate through the refrigerant passage 421b to prevent a temperature of the housing 421 from increasing according to an operation of the heater unit 423. Here, a difference between the temperature of the housing 421 and the temperature of the deposition material supply unit 422 may be relatively large due to circulation of the refrigerant. In this case, when the insulator 424 is not provided, the temperature of the reflector 427 connected to the housing 421 through the support connecting unit 425 may decrease, and thus, the deposition material may be adhered and harden on the reflector 427. Accordingly, not only a yield rate may decrease due to an increase in consumption of the deposition material, but also productivity may decrease due to a decrease in the number of repetitions of processes capable of using the deposition material. In addition, the deposition material adhered on the reflector 427 as described above may be vaporized or sublimated again when the temperature of the reflector 427 rapidly increases, and may be deposited on the display substrate DS. Accordingly, a thickness of the deposition material may exceed a pre-set thickness or the deposition material may be adhered in a portion of the display substrate DS, where the deposition material should not be adhered, thereby causing a malfunction or failure of the manufactured display device. However, by arranging the insulator 424 as described above, heat may be prevented from moving from the reflector 427 to the housing 421. In other words, the reflector 427 is hardly affected as a temperature of the housing 421 decreases, and thus, a temperature of the reflector 427 may not decrease due to cooling of the housing 421. In particular, compared to when the insulator 424 is not disposed, the temperature of the reflector 427 may be maintained about 5 degrees Celsius (°C) higher when the insulator 424 is disposed. The amount of deposition materials adhered on the top surface of the reflector 427 when the insulator 424 is disposed may be less than the amount of deposition materials adhered on the top surface of the reflector 427 when the insulator 424 is not disposed. Accordingly, the above-described issues may be prevented.

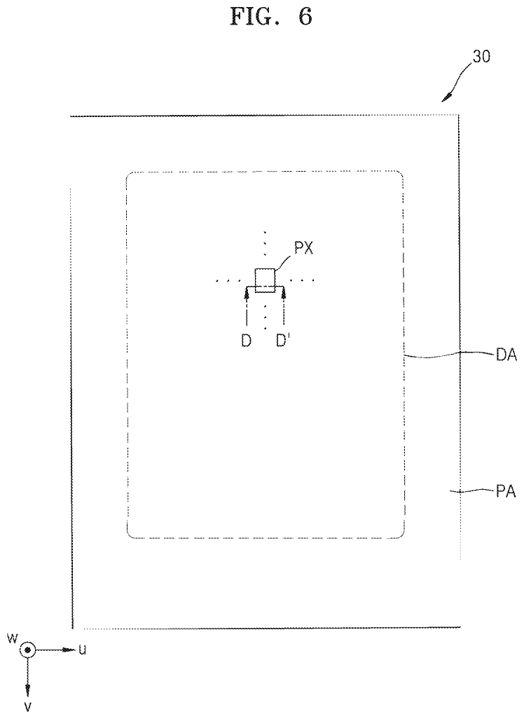

The deposition material may be deposited on the display substrate DS by passing through the mask assembly 470. The deposition material may be disposed on the display substrate DS in a pattern, in at least a portion of a display area DA of FIG. 6.

While such processes are performed, the pressure adjusting unit 440 may adjust pressure inside the chamber 410. In an embodiment, when at least one of the display substrate DS and the mask assembly 470 is inserted into the chamber 410, the pressure adjusting unit 440 may inject external air into the chamber 410 such that the pressure inside the chamber 410 is the same as or similar to atmospheric pressure, for example. Also, while a process is performed inside the chamber 410, the pressure adjusting unit 440 may discharge internal air of the chamber 410 to an outside of the chamber 410 such that the pressure inside the chamber 410 is lower than atmospheric pressure.

According to the apparatus 400 and method for manufacturing a display device, not only waste of the deposition material may be reduced, but also the number of times the same amount of deposition materials are deposited may be increased. In addition, according to the apparatus 400 and method for manufacturing a display device, a defect rate of the display device may be reduced.

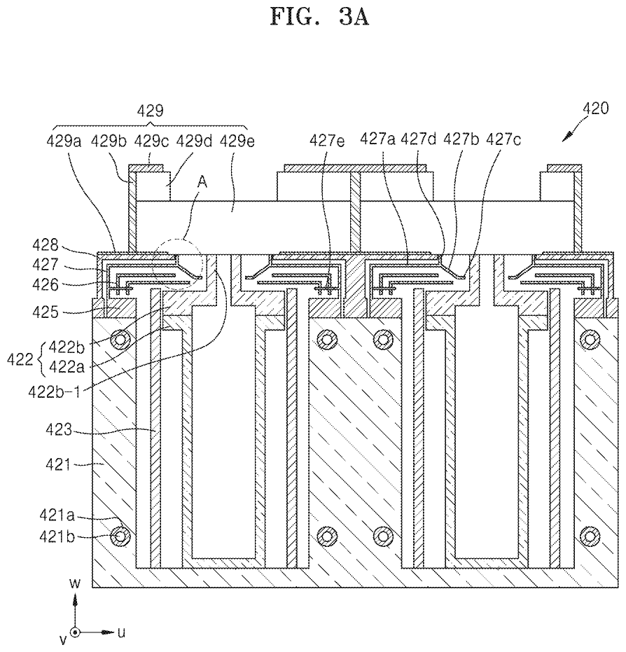

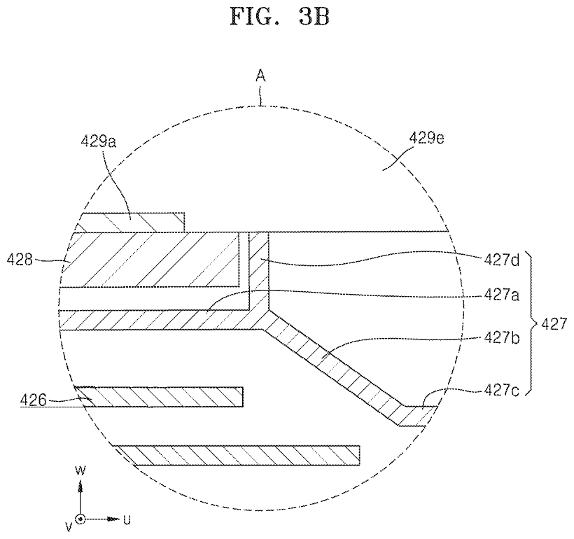

FIG. 3A is a cross-sectional view schematically showing another embodiment of the deposition source 420 of FIG. 1. FIG. 3B is an enlarged cross-sectional view of a region A of FIG. 3A.

Referring to FIGS. 3A and 3B, the deposition source 420 may include the housing 421, the deposition material supply unit 422, the heater unit 423, the support connecting unit 425, the heat sink 426, the reflector 427, the angle restricting plate support unit 428, and the angle restricting plate 429. The housing 421, the deposition material supply unit 422, the heater unit 423, the support connecting unit 425, the heat sink 426, the angle restricting plate support unit 428, and the angle restricting plate 429 are the same as or similar to those described with reference to FIGS. 1 to 2B, and thus, detailed descriptions thereof are omitted. The angle restricting plate 429 may include the base 429a, the first restricting plate 429b, the second restricting plate 429c, the third restricting plate 429d, and the fourth restricting plate 429e. The base 429a, the first restricting plate 429b, the second restricting plate 429c, the third restricting plate 429d, and the fourth restricting plate 429e are the same as or similar to those described with reference to FIGS. 1 to 2B, and thus, detailed descriptions thereof are omitted.

The reflector 427 may include the first portion 427a, the second portion 427b, the third portion 427c, a fourth portion 427d, and the protruding portion 427e. The first portion 427a, the second portion 427b, the third portion 427c, and the protruding portion 427e are the same as or similar to those described with reference to FIGS. 1 to 2B, and thus, detailed descriptions thereof are omitted.

The fourth portion 427d that is a shielding protrusion may protrude from the first portion 427a or the second portion 427b to the angle restricting plate support unit 428. The fourth portion 427d may be in the form of a flat plate and disposed perpendicular to one surface of the first portion 427a. At this time, the fourth portion 427d may be disposed to shield an end of the angle restricting plate support unit 428. Also, the fourth portion 427d may shield a space between one surface of the angle restricting plate support unit 428 and one surface of the first portion 427a, which face each other. The fourth portion 427d may be spaced apart from the end of the angle restricting plate support unit 428. In other words, the fourth portion 427d and the angle restricting plate support unit 428 may be separated from each other, thereby preventing heat transfer between the fourth portion 427d and the angle restricting plate support unit 428. In this case, when the heater unit 423 operates, a temperature of the fourth portion 427d may be higher than a temperature of the angle restricting plate support unit 428 because the fourth portion 427d is a portion of the reflector 427. Accordingly, a deposition material may not be adhered and harden on a side surface of the fourth portion 427d. In an embodiment, the fourth portion 427d may shield a space between one surface of the reflector 427 facing the angle restricting plate 429 and the angle restricting plate 429. In addition, in an embodiment, a side surface of the fourth portion 427d may face an end of a portion of the angle restricting plate 429, disposed above the reflector 427. Further, the fourth portion 427d may be separated from the angle restricting plate 429.

Thus, through such a structure, the deposition material may be prevented from being accumulated on one surface of the reflector 427.

Although not illustrated, the deposition source 420 may further include the insulator 424 of FIG. 2A.

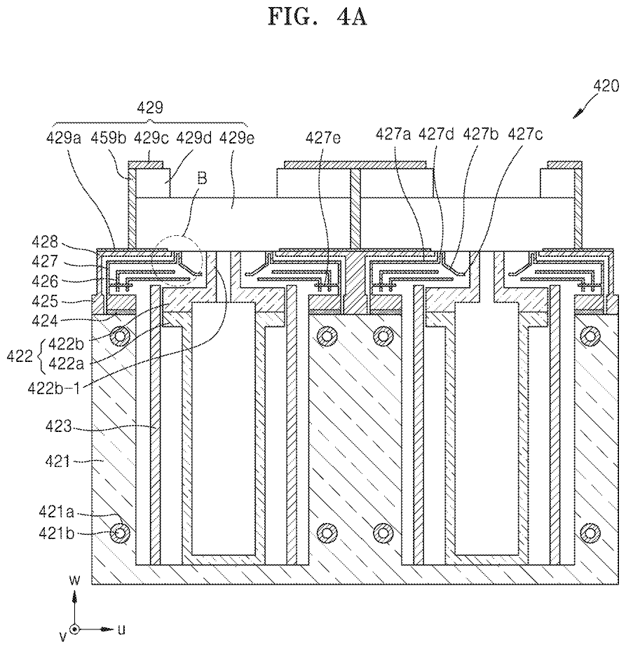

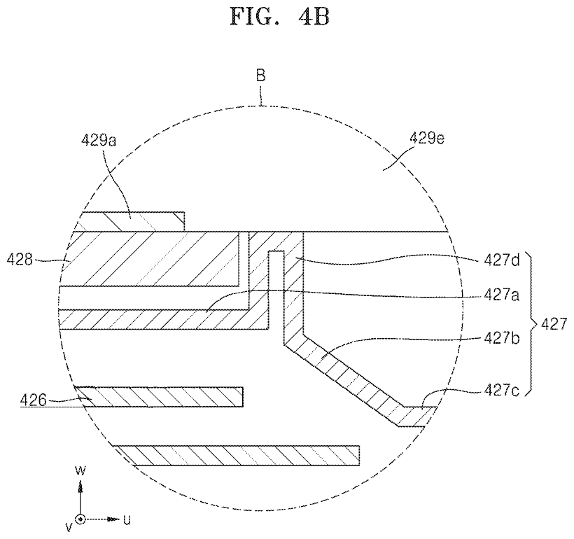

FIG. 4A is a cross-sectional view schematically showing another embodiment of the deposition source 420 of FIG. 1. FIG. 4B is an enlarged cross-sectional view of a region B of FIG. 4A.

Referring to FIGS. 4A and 4B, the deposition source 420 may include the housing 421, the deposition material supply unit 422, the heater unit 423, the insulator 424, the support connecting unit 425, the heat sink 426, the reflector 427, the angle restricting plate support unit 428, and the angle restricting plate 429. The housing 421, the deposition material supply unit 422, the heater unit 423, the insulator 424, the support connecting unit 425, the heat sink 426, the angle restricting plate support unit 428, and the angle restricting plate 429 are the same as or similar to those described with reference to FIGS. 1 to 2B, and thus, detailed descriptions thereof are omitted. The angle restricting plate 429 may include the base 429a, the first restricting plate 429b, the second restricting plate 429c, the third restricting plate 429d, and the fourth restricting plate 429e. The base 429a, the first restricting plate 429b, the second restricting plate 429c, the third restricting plate 429d, and the fourth restricting plate 429e are the same as or similar to those described with reference to FIGS. 1 to 2B, and thus, detailed descriptions thereof are omitted.

The reflector 427 may include the first portion 427a, the second portion 427b, the third portion 427c, the fourth portion 427d, and the protruding portion 427e. The first portion 427a, the second portion 427b, the third portion 427c, and the protruding portion 427e are the same as or similar to those described with reference to FIGS. 1 to 2B, and thus, detailed descriptions thereof are omitted.

The fourth portion 427d that is a shielding protrusion may protrude from the first portion 427a or the second portion 427b to the angle restricting plate support unit 428. The fourth portion 427d may be obtained as at least a portion of the first portion 427a or the second portion 427b is bent. The fourth portion 427d may be bent in a direction perpendicular to one surface of the first portion 427a and then bent again to be connected to the first portion 427a or the second portion 427b. At this time, a side surface of the fourth portion 427d may be disposed to shield an end of the angle restricting plate support unit 428. Also, the fourth portion 427d may shield a space between one surface of the angle restricting plate support unit 428 and one surface of the first portion 427a, which face each other. The side surface of the fourth portion 427d may be spaced apart from the end of the angle restricting plate support unit 428. In other words, all portions of the fourth portion 427d may be separated from the angle restricting plate support unit 428, thereby preventing heat transfer between the fourth portion 427d and the angle restricting plate support unit 428. In this case, when the heater unit 423 operates, a temperature of the fourth portion 427d may be higher than a temperature of the angle restricting plate support unit 428 because the fourth portion 427d is a portion of the reflector 427. Accordingly, a deposition material may not be adhered and harden on the side surface of the fourth portion 427d.

Also, in this case, the insulator 424 may block heat exchange between the housing 421 and the reflector 427. Accordingly, a temperature of the entirety of the reflector 427 may be prevented from decreasing due to cooling of the housing 421.

Thus, through such a structure, the deposition material may be prevented from being accumulated on one surface of the reflector 427.

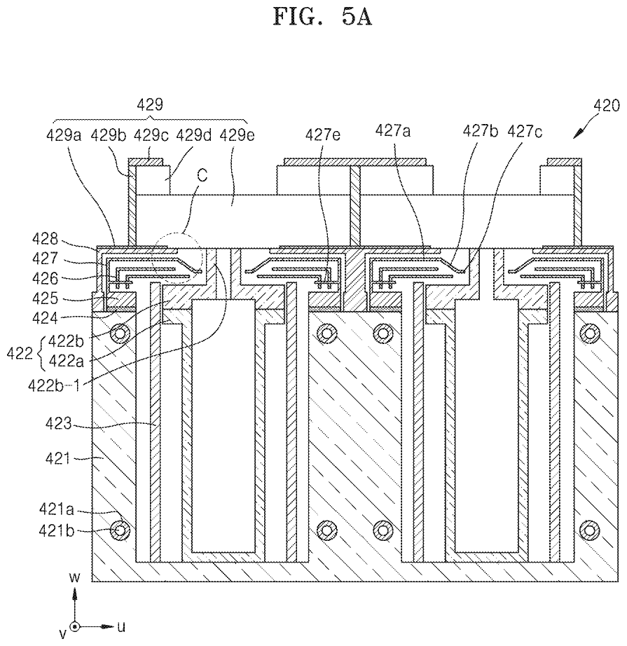

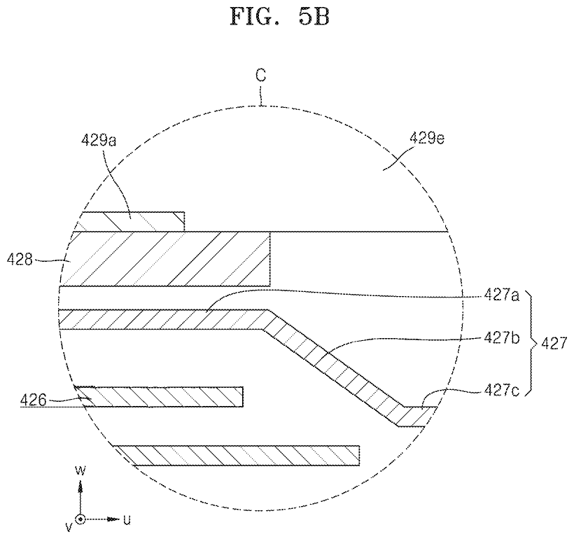

FIG. 5A is a cross-sectional view schematically showing an embodiment of the deposition source 420 of FIG. 1. FIG. 5B is an enlarged cross-sectional view of a region C of FIG. 5A.

Referring to FIGS. 5A and 5B, the deposition source 420 may include the housing 421, the deposition material supply unit 422, the heater unit 423, the insulator 424, the support connecting unit 425, the heat sink 426, the reflector 427, the angle restricting plate support unit 428, and the angle restricting plate 429. The housing 421, the deposition material supply unit 422, the heater unit 423, the insulator 424, the support connecting unit 425, the heat sink 426, the angle restricting plate support unit 428, and the angle restricting plate 429 are the same as or similar to those described above with reference to FIGS. 1 to 2B, and thus, detailed descriptions thereof are omitted. The angle restricting plate 429 may include the base 429a, the first restricting plate 429b, the second restricting plate 429c, the third restricting plate 429d, and the fourth restricting plate 429e. The base 429a, the first restricting plate 429b, the second restricting plate 429c, the third restricting plate 429d, and the fourth restricting plate 429e are the same as or similar to those described above with reference to FIGS. 1 to 2B, and thus, detailed descriptions thereof are omitted.

The reflector 427 may include the first portion 427a, the second portion 427b, the third portion 427c, and the protruding portion 427e. The first portion 427a, the second portion 427b, the third portion 427c, and the protruding portion 427e are the same as or similar to those described above with reference to FIGS. 2A and 2B, and thus, detailed descriptions thereof are omitted.

An end of the angle restricting plate support unit 428 may match a point where the first portion 427a and the second portion 427b are connected to each other. In other words, the end of the angle restricting plate support unit 428 may overlap, in the w direction, a point where the reflector 427 is bent. Accordingly, heat may move to the outside from a space between the angle restricting plate support unit 428 and the reflector 427. In particular, the deposition material may be prevented from being accumulated in the space between the angle restricting plate support unit 428 and the reflector 427 because heat is contained in the space between the angle restricting plate support unit 428 and the reflector 427.

In addition, the third portion 427c of the reflector 427 is disposed as close as possible to an outer surface of the deposition material supply unit 422 to prevent the deposition material being accumulated on the reflector 427.

Thus, according to such a structure, the deposition material may be prevented from being accumulated on one surface of the reflector 427.

In addition, the forms of the reflector 427 and angle restricting plate support unit 428 illustrated in FIGS. 5A and 5B may also be applied to FIG. 2A.

FIG. 6 is a plan view schematically showing a display device 30 according to an embodiment.

Referring to FIG. 6, the display device 30 may include the display area DA and a peripheral area PA disposed outside the display area DA. The display device 30 may provide an image via an array of a plurality of sub-pixels PX arranged in the display area DA in two dimensions. Some of the plurality of sub-pixels PX, some other sub-pixels PX of the plurality of sub-pixels PX, and additional some other sub-pixels PX of the plurality of sub-pixels PX may emit light of different colors. In an embodiment, some of the plurality of sub-pixels PX, some other sub-pixels PX of the plurality of sub-pixels PX, and additional some other sub-pixels PX of the plurality of sub-pixels PX may emit red light, green light, and blue light, respectively. In another embodiment, the plurality of sub-pixels PX may emit white light, for example.

The peripheral area PA is an area where an image is not provided, and may entirely or partially surround the display area DA. A driver or the like configured to provide an electrical signal or power to a sub-pixel circuit corresponding to each of the sub-pixels PX may be arranged in the peripheral area PA. A pad that is a region to which an electronic device or a printed circuit board may be electrically connected may be disposed in the peripheral area PA.

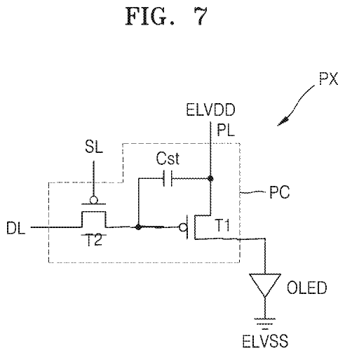

Hereinafter, the display device 30 is described as including an organic light-emitting diode OLED (see FIG. 7) as a light-emitting element, but the display device 30 of the disclosure is not limited thereto. In another embodiment, the display device 30 may be a light-emitting display device including an inorganic light-emitting diode, i.e., may be an inorganic light-emitting display device. The inorganic light-emitting diode may include a PN junction diode including inorganic semiconductor-based materials. When a voltage is applied to a PN junction diode in a forward direction, holes and electrons are injected, and energy generated by recombination of the holes and electrons is converted into light energy, and thus, light of a predetermined color may be emitted. The inorganic light-emitting diode may have a width of several to several hundred micrometers, and in some embodiments, the inorganic light-emitting diode may be also referred to as a micro light-emitting diode (“LED”). In another embodiment, the display device 30 may be a quantum dot light-emitting display device.

FIG. 7 is a circuit diagram schematically showing a circuit of the display device 30 of FIG. 6. FIG. 8 is a cross-sectional view showing a portion of the display device 30 of FIG. 6. FIG. 8 is a cross-sectional view of the display device 30 taken along line D-D′ of FIG. 6.

Referring to FIGS. 7 and 8, each sub-pixel PX may include a sub-pixel circuit PC and a display element, e.g., the organic light-emitting diode OLED, connected to the sub-pixel circuit PC. The sub-pixel circuit PC may include a first thin-film transistor T1, a second thin-film transistor T2, and a storage capacitor Cst. Each sub-pixel PX may emit, red, green, blue, or white light through the organic light-emitting diode OLED, for example.

The second thin-film transistor T2 is a switching thin-film transistor, is connected to a scan line SL and a data line DL, and may transmit a data voltage input from the data line DL to the first thin-film transistor T1 based on a switching voltage input from the scan line SL. The storage capacitor Cst is connected to the second thin-film transistor T2 and a driving voltage line PL, and may store a voltage corresponding to a difference between a voltage received from the second thin-film transistor T2 and a first power voltage ELVDD supplied to the driving voltage line PL.

The first thin-film transistor T1 is a driving thin-film transistor, is connected to the driving voltage line PL and the storage capacitor Cst, and may control a driving current flowing through the organic light-emitting diode OLED from the driving voltage line PL in response to a value of a voltage stored in the storage capacitor Cst. The organic light-emitting diode OLED may emit light of a predetermined luminance according to the driving current. An opposite electrode (e.g., a cathode) of the organic light-emitting diode OLED may receive a second power voltage ELVSS.

In FIG. 7, the sub-pixel circuit PC includes two thin-film transistors and one storage capacitor, but the disclosure is not limited thereto. The number of thin-film transistors and the number of storage capacitors may vary depending on a design of the sub-pixel circuit PC. In an embodiment, the sub-pixel circuit PC may further include four or more thin-film transistors, in addition to the two thin-film transistors described above, for example.

The display device 30 may include a stack structure of a sub-pixel circuit layer PCL, a display element layer DEL, and an encapsulation layer 300. Here, a display substrate (not shown) may be a concept including the substrate 100, the sub-pixel circuit layer PCL, and some layers of the display element layer DEL. In other words, the display substrate may include from the substrate 100 to a bank layer 1117.

The substrate 100 may have a multi-layer structure including an inorganic layer and a base layer including polymer resin. In an embodiment, the substrate 100 may include a barrier layer of an inorganic insulating layer and the base layer including the polymer resin, for example. In an embodiment, the substrate 100 may include a first base layer 101, a first barrier layer 102, a second base layer 103, and a second barrier layer 104, which are sequentially stacked, for example. The first base layer 101 and the second base layer 103 may include polyimide (“PI”), polyethersulfone (“PES”), polyarylate, polyetherimide (“PEI”), polyethylene naphthalate (“PEN”), polyethylene terephthalate (“PET”), polyphenylene sulfide (“PPS”), polycarbonate, cellulose triacetate (“TAC”), and/or cellulose acetate propionate (“CAP”). The first barrier layer 102 and the second barrier layer 104 may include an inorganic insulating material such as silicon oxide, silicon oxynitride, and/or silicon nitride. The substrate 100 may be flexible.

The sub-pixel circuit layer PCL may be disposed on the substrate 100. FIG. 8 illustrates that the sub-pixel circuit layer PCL includes a thin-film transistor TFT, and a buffer layer 1111, a first gate insulating layer 1112, a second gate insulating layer 1113, an inter-insulating layer 1114, a first planarization insulating layer 1115, and a second planarization insulating layer 1116, which are disposed below and/or on components of the thin-film transistor TFT.

The buffer layer 1111 may reduce or block penetration of foreign materials, moisture, or ambient air from a bottom portion of the substrate 100 and may provide a flat surface on the substrate 100. The buffer layer 1111 may include an inorganic insulating material, such as silicon oxide, silicon oxynitride, or silicon nitride, and may have a single layer or multi-layer structure including such a material.

The thin-film transistor TFT on the buffer layer 1111 may include a semiconductor layer Act, and the semiconductor layer Act may include polysilicon (poly-Si). In an alternative embodiment, the semiconductor layer Act may include amorphous silicon (a-Si), an oxide semiconductor, or an organic semiconductor. The semiconductor layer Act may include a channel region C, and a drain region D and a source region S, which are arranged on opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), or titanium (Ti), and may be formed in a multi-layer or single layer including the conductive material.

The first gate insulating layer 1112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). ZnOₓ may be ZnO and/or ZnO₂.

The second gate insulating layer 1113 may be provided to cover the gate electrode GE. Like t he first gate insulating layer 1112, the second gate insulating layer 1113 may include an inorganic insulating material, such as SiO₂, SiNₓ, SiON, Al₂O₃, TiO₂, Ta₂O₅, HfO₂, and/or ZnOₓ. ZnOₓ may be ZnO and/or ZnO₂.

An upper electrode Cst2 of the storage capacitor Cst may be disposed above the second gate insulating layer 1113. The upper electrode Cst2 may overlap the gate electrode GE below the upper electrode Cst2. Here, the upper electrode Cst2 and the gate electrode GE, which overlap each other with the second gate insulating layer 1113 between the upper electrode Cst2 and the gate electrode GE, may form the storage capacitor Cst. In other words, the gate electrode GE may operate as a lower electrode Cst1 of the storage capacitor Cst.

As such, the storage capacitor Cst and the thin-film transistor TFT may overlap each other. According to some embodiments, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multi-layer including such a material.

The inter-insulating layer 1114 may cover the upper electrode Cst2. The inter-insulating layer 1114 may include SiO₂, SiNₓ, SiON, Al₂O₃, TiO₂, Ta₂O₅, HfO₂, or ZnOₓ. ZnOₓ may be ZnO and/or ZnO₂. The inter-insulating layer 1114 may be a single layer or multi-layer including the inorganic insulating material described above.

A drain electrode DE and a source electrode SE may each be disposed on the inter-insulating layer 1114. The drain electrode DE and the source electrode SE may be respectively connected to the drain region D and the source region S through contact holes of insulating layers below the drain electrode DE and the source electrode SE. The drain electrode DE and the source electrode SE may include a material having substantially high conductivity. The drain electrode DE and the source electrode SE may include a conductive material including Mo, Al, Cu, or Ti, and may be formed in a multi-layer or single layer including the above material. In an embodiment, the drain electrode DE and the source electrode SE may have a multi-layer structure of Ti/Al/Ti.

The first planarization insulating layer 1115 may cover the drain electrode DE and the source electrode SE. The first planarization insulating layer 1115 may include an organic insulating material, such as a general-purpose polymer, e.g., polymethylmethacrylate (“PMMA”) or polystyrene (“PS”), a polymer derivate having a phenol-based group, an acrylic-based polymer, an imide-based polymer, an arylether-based polymer, an amide-based polymer, a fluorine-based polymer, a p-xylene-based polymer, a vinyl alcohol-based polymer, or any combinations thereof.

The second planarization insulating layer 1116 may be disposed on the first planarization insulating layer 1115. The second planarization insulating layer 1116 may include the same material as that of the first planarization insulating layer 1115, and may include an organic insulating material, such as a general-purpose polymer such as polymethylmethacrylate (“PMMA”) or polystyrene (“PS”), a polymer derivative having a phenol-based group, an acryl-based polymer, an imide-based polymer, an arylether-based polymer, an amide-based polymer, a fluorine-based polymer, a p-xylene-based polymer, a vinyl alcohol-based polymer, or any combinations thereof.

The display element layer DEL may be disposed on the sub-pixel circuit layer PCL having the above-described structure. The display element layer DEL includes the organic light-emitting diode OLED as a display element (i.e., a light-emitting element), and the organic light-emitting diode OLED may have a stack structure of a sub-pixel electrode 210, the intermediate layer 220, and a common electrode 230. The organic light-emitting diode OLED may emit, e.g., red, green, or blue light or red, green, blue, or white light. The organic light-emitting diode OLED emits a light through an emission area, and the emission area may be defined as the sub-pixel PX.

The sub-pixel electrode 210 of the organic light-emitting diode OLED may be electrically connected to the thin-film transistor TFT through contact holes defined in the second planarization insulating layer 1116 and the first planarization insulating layer 1115 and a contact metal CM disposed on the first planarization insulating layer 1115.

The sub-pixel electrode 210 may include a conductive oxide, such as indium tin oxide (“ITO”), indium zinc oxide (“IZO”), zinc oxide (ZnO), indium oxide (In₂O₃), indium gallium oxide (“IGO”), and/or aluminum zinc oxide (“AZO”). In another embodiment, the sub-pixel electrode 210 may include a reflective layer including Ag, Mg, Al, Pt, Pd, Au, Ni, Nd, Ir, Cr, and/or any combinations thereof. In another embodiment, the sub-pixel electrode 210 may further include a layer including or consisting of ITO, IZO, ZnO, and/or In₂O_{3,} on/below the reflective layer.

The bank layer 1117 defining an opening 117OP exposing the center portion of the sub-pixel electrode 210 may be disposed on the sub-pixel electrode 210. The bank layer 1117 may include an organic insulating material and/or an inorganic insulating material. The opening 117OP may define an emission area of light emitted from the organic light-emitting diode OLED. In an embodiment, the size(e.g., width) of the opening 117OP may correspond to the size(e.g., width) of the emission area, for example. Accordingly, the size (e.g., width) of the sub-pixel PX may be dependent on the size (e.g., width) of the opening 117OP of the corresponding bank layer 1117.

The intermediate layer 220 may include an emission layer 2222 formed to correspond to the sub-pixel electrode 210. The emission layer 2222 may include a high-molecular weight organic material or low-molecular weight organic material, which emit light of a predetermined color. In an alternative embodiment, the emission layer 2222 may include an inorganic light-emitting material or quantum dots. The emission layer 2222 may be manufactured by an apparatus for manufacturing a display device, described above.

In an embodiment, the intermediate layer 220 may include the first functional layer 2221 and a second functional layer 2223, which are respectively disposed below and on the emission layer 2222. The first functional layer 2221 may include a hole transport layer (“HTL”) or may include an HTL and a hole injection layer (“HIL”), for example. The second functional layer 2223 is a component disposed on the emission layer 2222, and may include an electron transport layer (“ETL”) and/or an electron injection layer (“EIL”). Like the common electrode 230 described below, the first functional layer 2221 and/or the second functional layer 2223 may be a common layer formed to cover an entirety of the substrate 100.

At least one layer among the intermediate layer 220 may be manufactured by the apparatus for manufacturing a display device, described above. The resolution of the display device 30 may vary depending on how many of layers of the intermediate layer 220, which are spaced apart from each other through the apparatus for manufacturing a display device, are arranged in a predetermined area. Here, when at least one of the layers of the intermediate layer 220 is formed through the apparatus for manufacturing a display device, a relatively large number of layers may be arranged in the predetermined area by reducing a distance between the layers of the intermediate layer 220, which are spaced apart from each other.

The common electrode 230 may be disposed on the sub-pixel electrode 210 and overlap the sub-pixel electrode 210. The common electrode 230 may include a conductive material with a relatively low work function. In an embodiment, the common electrode 230 may include a (semi-)transparent layer including Ag, Mg, Al, Pt, Pd, Au, Ni, Nd, Ir, Cr, lithium (Li), calcium (Ca), and/or any alloys thereof. In an alternative embodiment, the common electrode 230 may further include a layer including ITO, IZO, ZnO, and/or In₂O₃, on the (semi-)transparent layer including such a material. The common electrode 230 may be integrally (or unitarily) formed to cover an entirety of the substrate 100.

The encapsulation layer 300 may be disposed on the display element layer DEL and cover the display element layer DEL. The encapsulation layer 300 includes at least one inorganic encapsulation layer and at least one organic encapsulation layer, and according to an embodiment, FIG. 8 illustrates that the encapsulation layer 300 includes a first inorganic encapsulation layer 310, an organic encapsulation layer 320, and a second inorganic encapsulation layer 330, which are sequentially stacked on each other.

The first inorganic encapsulation layer 310 and the second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and/or polyethylene. According to an embodiment, the organic encapsulation layer 320 may include acrylate. The organic encapsulation layer 320 may be formed by curing monomer or applying polymer. The organic encapsulation layer 320 may be transparent.

Although not illustrated, a touch sensor layer may be disposed on the encapsulation layer 300, and an optical functional layer may be disposed on the touch sensor layer. The touch sensor layer may obtain coordinate information according to an external input, e.g., a touch event. The optical functional layer may reduce reflectance of light (external light) incident from the outside towards a display device, and/or enhance color purity of light emitted from the display device. In an embodiment, the optical functional layer may include a retarder and/or a polarizer. The retarder may be a film type or liquid crystal coating type, and may include a λ/2 retarder and/or a λ/4 retarder. The polarizer may also be a film type or a liquid crystal coating type. The film type may include an elongated synthetic resin film, and the liquid crystal coating type may include liquid crystals arranged in a predetermined arrangement. The retarder and the polarizer may further include a protection film.

An adhesive member may be disposed between the touch sensor layer and the optical functional layer. A general adhesive member known in the related art may be employed as the adhesive member without limitation. The adhesive member may be a pressure sensitive adhesive (“PSA”).

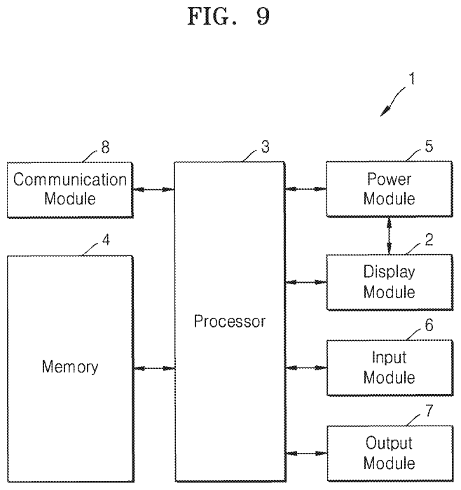

FIG. 9 is a block diagram of an electronic device 1 according to an embodiment.

Referring to FIG. 9, the electronic device 1 according to an embodiment may include a display module 2 including a display device described above, a processor 3, a memory 4, and a power module 5.

The processor 3 may include at least one of a central processing unit (“CPU”), an application processor (“AP”), a graphics processing unit (“GPU”), a communication processor (“CP”), an image signal processor (“ISP”), and a controller. According to an embodiment, the processor 3 may be divided into two or more processors from a functional or structural perspective. In an embodiment, the processor 3 may include a main processor in the form of a first driving chip including a CPU, and an auxiliary processor in the form of a second driving chip including a controller that receives an image signal from the main processor and processes the image signal according to an interface specification of the display module 2, for example.

The memory 4 may include at least one of a non-volatile memory and a volatile memory. In an embodiment, the memory 4 may be connected to the display device. The memory 4 may store data information desired for operations of the processor 3 or the display module 2. When the processor 3 executes an application stored in the memory 4, an image data signal and/or an input control signal is transmitted to the display module 2, and the display module 2 may process the received signal and output image information on a display screen.

The power module 5 may include a power supply module, such as a power adapter or a battery device, and a power conversion module configured to convert power supplied by the power supply module to generate power desired for operations of the electronic device 1. Power conversion performed by the power conversion module may include direct current (“DC”)-DC conversion, alternating current (“AC”)-DC conversion, and DC-AC conversion, but is not limited thereto.

The electronic device 1 may further include an input module 6, a non-image output module (also referred to as an output module) 7, and/or a communication module 8.

The input module 6 may provide input information to the processor 3 and/or the display module 2. The input module 6 may include not only a physical button, a keyboard, and a microphone, but also various sensor modules. Examples of the sensor modules may include a touch sensor, a pressure sensor, a distance sensor, a position sensor, a digitizer, a motion recognition sensor, a camera sensor, a light-reception sensor, a photoelectric conversion sensor, and a temperature sensor, as well as biosensors, such as a blood pressure sensor, a blood sugar sensor, an electrocardiogram sensor, and a heart rate sensor.

The non-image output module 7 may receive information other than an image received from the processor 3, and provide the information to a user. Examples of the non-image output module 7 include an audio module, a haptic module, and a light-emitting module, and may include other functional modules unique to an electronic device (e.g., a cooling module of a refrigerator).

The communication module 8 is a module in charge of transmission and reception of information between the electronic device 1 and an external device, and may include a receiver and a transmitter. The communication module 8 may include various wireless communication modules, such as a mobile communication module, a Wi-Fi module, and a Bluetooth module, and various wired communication modules.

At least one of the components of the electronic device 1 may be included in a display device according to the above-described embodiments. Some of individual modules functionally included in one module may be included in the display device and others may be provided separately from the display device. In an embodiment, the display device may include the display module 2, and the processor 3, the memory 4, and the power module 5 may be provided in the form of other devices in the electronic device 1 other than the display device. In another example, the power module 5 may be provided in the display device and provide power to the processor 3 and the memory 4 provided in the electronic device 1 other than the display device, for example, but an embodiment is not limited thereto.

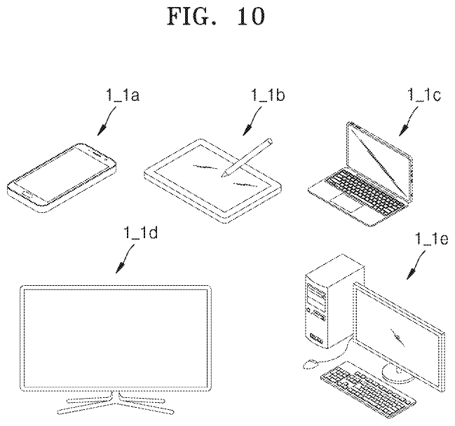

FIGS. 10 to 12 are schematic diagrams of an electronic device according to some embodiments. FIGS. 10 to 12 illustrate examples of various electronic devices to which a display device in embodiments is applied.

FIG. 10 illustrates, as examples of an electronic device, a smartphone 1_1a, a tablet personal computer 1_1b, a laptop computer 1_1c, a television (“TV”) 1_1d, and a desktop monitor 1_1e.

The smartphone 1_1a may include a communication module and an input module such as a touch sensor, in addition to the display module 2 (see FIG. 9). The smartphone 1_1a may process information received through the communication module or another input module and display the information through a display module of a display device.

The tablet personal computer 1_1b, the laptop computer 1_1c, the TV 1_1d, or the desktop monitor 1_1e also includes a display module and an input module like the smartphone 1_1a, and in some cases, may further include a communication module.

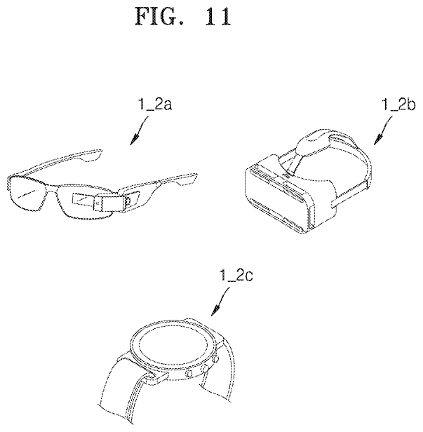

FIG. 11 illustrates a case where an electronic device including a display module is applied to a wearable electronic device. The wearable electronic device may include smart glasses 1_2a, a head-mount display 1_2b, or a smart watch 1_2c.

The smart glasses 1_2a and the head-mount display 1_2b may include a display module that is configured to emit a display image, and a reflector that is configured to reflect the emitted display image and provides the same to a user's eyes, thereby providing a virtual reality or augmented reality screen to the user.

The smart watch 1_2c may include a biosensor as an input device, and provide, to a user through a display module, biometric information recognized through the biosensor.

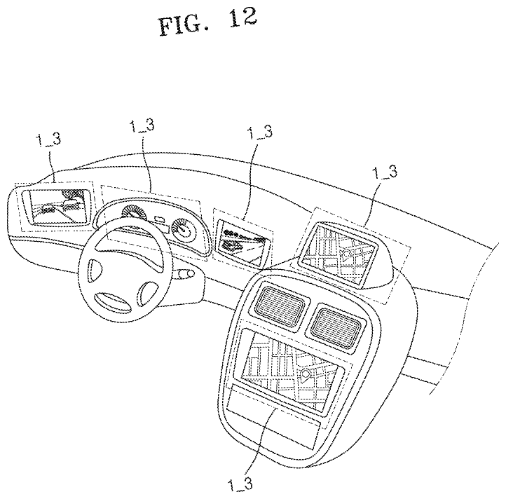

FIG. 12 illustrates a case where an electronic device 1_3 including a display module is applied to a vehicle. In an embodiment, the electronic device 1_3 may be applied to a dashboard or center fascia of the vehicle, or may be applied to a center information display (“CID”) arranged on the dashboard of the vehicle or to a room mirror display replacing a side mirror, for example.

Although not illustrated, examples of an electronic device to which a display device according to the embodiments is applied may include not only devices that mainly display screens, such as billboards, electronic boards, or game consoles, but also various home appliances that display information through display modules, such as refrigerators, washing machines, dryers, air conditioners, or robot vacuum cleaners. In addition, when a display module includes a function of transmitting light, the display module may be applied to an electronic device, such as a smart window or a transparent display device that display a background and a display image together. Types of electronic devices according to the disclosure is not limited to those described above, and application of various other electronic devices that are not described may also be possible.

Accordingly, the electronic device described above may provide a clear image.

In an apparatus for manufacturing a display device and a method for manufacturing a display device, in embodiments, the amount of deposition materials deposited in a section where a temperature rapidly changes in a deposition source may be reduced.

In an apparatus for manufacturing a display device and a method for manufacturing a display device, in embodiments, the lifespan of a deposition source may be increased and a deposition material may be efficiently used.

It should be understood that embodiments described herein should be considered in a descriptive sense only and not for purposes of limitation. Descriptions of features or advantages within each embodiment should typically be considered as available for other similar features or advantages in other embodiments. While one or more embodiments have been described with reference to the drawing figures, it will be understood by those of ordinary skill in the art that various changes in form and details may be made therein without departing from the spirit and scope as defined by the following claims.

What is claimed is:

1. An apparatus for manufacturing a display device, the apparatus comprising:
a chamber in which a substrate is disposed; and
a deposition source which is disposed inside the chamber and supplies a deposition material onto the substrate, the deposition source comprising:
a housing including therein a passage through which a refrigerant circulates;
a deposition material supply unit disposed inside the housing, storing the deposition material, and including a nozzle which guides the deposition material to the outside;
a heater unit which is disposed outside the deposition material supply unit and heats the deposition material supply unit;
a reflector which is disposed above the housing and shields an internal space of the housing; and
an insulator disposed between the reflector and the housing to block movement of heat.

2. The apparatus of claim 1, wherein the deposition source further comprises a heat sink disposed between the reflector and the deposition material supply unit.

3. The apparatus of claim 1, wherein the insulator comprises at least one of polyetheretherketone, wholly aromatic polyimide, carbon composite, and ceramic.

4. The apparatus of claim 1, wherein the deposition source further comprises an angle restricting plate which is disposed on the reflector and restricts a path of the deposition material ejected from the nozzle.

5. The apparatus of claim 4, wherein the reflector comprises a shielding protrusion which shields a space between one surface of the reflector, on which the angle restricting plate is disposed, and the angle restricting plate.

6. The apparatus of claim 5, wherein a side surface of the shielding protrusion faces an end of a portion of the angle restricting plate, disposed on the reflector.

7. The apparatus of claim 5, wherein the shielding protrusion is separated from the angle restricting plate.

8. The apparatus of claim 1, wherein at least a portion of the reflector is bent.

9. An apparatus for manufacturing a display device, the apparatus comprising:
a chamber in which a substrate is disposed; and
a deposition source which is disposed inside the chamber and supplies a deposition material onto the substrate, the deposition source comprising:
a housing including therein a passage through which a refrigerant circulates;
a deposition material supply unit which is disposed inside the housing and stores the deposition material, the deposition material supply unit including:
a nozzle guiding the deposition material to the outside;
a heater unit which is disposed outside the deposition material supply unit and heats the deposition material supply unit;
a reflector which is disposed above the housing and shields an internal space of the housing;
an angle restricting plate which is disposed on the reflector and restricts a path of the deposition material ejected from the nozzle; and
an angle restricting plate support unit connected to the housing and the angle restricting plate and supporting the angle restricting plate,
wherein an end of the angle restricting plate support unit disposed on the reflector corresponds to a point of the reflector at which the reflector starts to bend.

10. The apparatus of claim 9, wherein the reflector comprises a shielding protrusion which shields a space between the angle restricting plate support unit and the reflector.

11. The apparatus of claim 10, wherein a side surface of the shielding protrusion faces the end of the angle restricting plate support unit.

12. The apparatus of claim 10, wherein the shielding protrusion is separated from the angle restricting plate support unit.

13. A method of manufacturing a display device, the method comprising:
arranging a substrate and a mask assembly inside a chamber;
supplying a deposition material by a deposition source including a deposition material supply unit storing the deposition material;
when the deposition material is supplied:
matching an end of a portion of an angle restricting plate support unit, on which an angle restricting plate is disposed, to a bending point of a reflector disposed around the deposition material supply unit and including at least a portion which is bent,
blocking a space between the angle restricting plate support unit and the reflector disposed on a top surface of the deposition material supply unit, or blocking a heat exchange between the reflector and a housing in which the deposition material supply unit is accommodated and through which a refrigerant circulates, the housing including a top surface on which the reflector is disposed; and
depositing the deposition material on the substrate through the mask assembly.

14. The method of claim 13, further comprising arranging an insulator between the reflector and the housing.

15. The method of claim 14, wherein the insulator comprises at least one of polyetheretherketone, wholly aromatic polyimide, carbon composite, and ceramic.

16. The method of claim 13, wherein the space between the angle restricting plate support unit and the reflector is shielded by a shielding protrusion protruding from the reflector.

17. The method of claim 16, wherein a side surface of the shielding protrusion faces the end of the portion of the angle restricting plate support unit.

18. The method of claim 16, wherein the shielding protrusion is separated from the angle restricting plate support unit.

19. An electronic device comprising:
the display device manufactured by the apparatus of claim 1; and
a memory connected to the display device.

20. The electronic device of claim 19, wherein the electronic device comprises a smartphone, a tablet personal computer, a laptop computer, a desk monitor, smart glasses, a head-mounted display, a smart watch, a vehicle, a billboard, an electronic board, a game console, a refrigerator, a washing machine, a dryer, an air conditioner, or a robot vacuum cleaner.
